(19) United States
(12) Patent Application Publication
(10) Pub. No.: US 2026/0164863 A1
(43) Pub. Date: Jun. 11, 2026

(54) MICRO LIGHT-EMITTING DEVICE AND MANUFACTURING METHOD THEREOF

(71) Applicant: PlayNitride Display Co., Ltd., Zhunan Township (TW)

(72) Inventors: Shen-Jie WANG, Zhunan Township (TW); Yu-Yun LO, Zhunan Township (TW); Yen-Lin LAI, Zhunan Township (TW); Tzu-Yang LIN, Zhunan Township (TW)

(21) Appl. No.: 19/180,565

(22) Filed: Apr. 16, 2025

Related U.S. Application Data
(63) Continuation-in-part of application No. 17/516,004, filed on Nov. 1, 2021, now abandoned.

(30) Foreign Application Priority Data
Jun. 17, 2021 (TW) 110122183

(51) Int. Cl. H10H 20/82; H10H 20/01; H10H 20/831; H10H 20/833; H10H 20/84

(52) U.S. Cl. CPC H10H 20/82; H10H 20/017; H10H 20/032; H10H 20/034; H10H 20/8314; H10H 20/833; H10H 20/84

(57) ABSTRACT

A micro light-emitting device has an epitaxial die having a top surface, a bottom surface and a plurality of sidewalls connected between the top surface and the bottom surface. A roughness of at least one part of the surface of at least one of the sidewalls is smaller than or equal to 10 nm, or an etch-pit density of the at least one part of the surface is smaller than 10⁸/cm², or a flatness tolerance of the at least one part of the surface is greater than 0.1 times a thickness of the epitaxial die. Therefore, the serious attenuation of the peak external quantum efficiency is prevented due to the sidewall damage effect after the light-emitting device is miniaturized.

### CROSS-REFERENCE TO RELATED APPLICATIONS

This application is a continuation in part application of U.S. patent application filed on Nov. 1, 2021 and having application Ser. No. 17/516,004, the entire contents of which are hereby incorporated herein by reference.

This application is based upon and claims priority under 35 U.S.C. 119 from Taiwan Patent Application No. 110122183 filed on Jun. 17, 2021, which is hereby specifically incorporated herein by this reference thereto.

### BACKGROUND OF THE INVENTION

### 1. Field of the Invention

The present invention is related to a micro light-emitting device, and more particularly to a micro light-emitting device formed by natural epitaxial growth and a manufacturing method thereof.

### 2. Description of the Prior Arts

The light-emitting device is miniaturized to be used in different products or applications. As the size of the light-emitting device is reduced to the micron level, a lower peak external quantum efficiency (EQE) of a smaller micro light-emitting device is obviously attenuated. As a red micro light-emitting device as an example, it's initial EQE is restricted by the epitaxial material and so that is lower, and accordingly the attenuation issue is more serious.

An epitaxial layer is provided and then separated to a plurality of micro dies through a patterned etching procedure, such as reactive-ion etching (RIE). Since the micro die is formed by etching, it has the issue of attenuating EQE. During the patterned etching procedure, the bonds between the atoms on sidewall surfaces of the micro die are broken to form dangling bonds, resulting in the generation of non-radiative recombination sites of carriers. This phenomenon is called the sidewall damage. Use the wet etching as an example, the sidewall surfaces of the micro die have the uneven concave-convex patterns. A large number of dangling bonds is formed on the uneven concave-convex patterns by etching. When electrons are close to the sidewall surfaces of the micro die, the electron-hole recombination is easily happened through these unstable floating bonds to form a current leakage.

Furthermore, as the size of the micro die is reduced, a ratio of the size of the lateral sidewalls and the total size is increased, and the sidewall damage effect is more obvious.

To overcome the shortcomings, the present invention provides a micro light-emitting device formed by natural epitaxial growth to mitigate or to obviate the aforementioned problems.

### SUMMARY OF THE INVENTION

The objective of the present invention provides a micro light-emitting device and a manufacturing method thereof.

To achieve the foregoing objective, the micro light-emitting device of the present invention has a micro-sized epitaxial die including a top surface, a bottom surface and a plurality of sidewalls connected between the top surface and the bottom surface, and having from bottom to top:
a first type epitaxial semiconductor layer;
a light-emitting layer formed on the first type epitaxial semiconductor layer; and
a second type epitaxial semiconductor layer formed on the light-emitting layer;
wherein at least one part of a surface of at least one of the plurality of sidewalls has a natural epitaxial growth characteristic, including a root mean square roughness of the at least one part of the surface of at least one of the sidewalls is smaller than or equal to 10 nm, or an etch-pit density of the at least one part of the surface is smaller than 10⁸/cm², or a flatness tolerance of the at least one part of the surface is greater than 0.1 times a thickness of the micro-sized epitaxial die.

Since the micro-sized epitaxial die of the present invention is formed by the natural epitaxial growth, the root mean square roughness and the etch-pit density of the sidewalls of the micro-sized epitaxial die are smaller and the flatness tolerance of the sidewalls of the micro-sized epitaxial die is greater than those of the etched surface of the sidewalls of the conventional micro die. Based on the above characteristics of the micro-sized epitaxial die, a number of dangling bonds on each sidewall is decreased so that to ease the sidewall damage effect. Therefore, severe attenuation of the EQE caused by the sidewall damage effect can be prevented while the light-emitting device is miniaturized.

To achieve the foregoing objective, another micro light-emitting device forming on a growth substrate which has a patterned structure defined with a growth area. The micro light-emitting device has:
a micro-sized epitaxial die including a top surface, a bottom surface, and a plurality of sidewalls connected between the top surface and the bottom surface, and having from bottom to top:
   a first type epitaxial semiconductor layer;
   a light-emitting layer formed on the first type epitaxial semiconductor layer; and
   a second type epitaxial semiconductor layer formed on the light-emitting layer
wherein at least one part of a surface of at least one of the plurality of sidewalls has a natural epitaxial growth characteristic, including a root mean square roughness of the at least one part of the surface of at least one of the sidewalls is smaller than or equal to 10 nm, or an etch-pit density of the at least one part of the surface is smaller than 10⁸/cm², or a flatness tolerance of the at least one part of the surface is greater than 0.1 times a thickness of the micro-sized epitaxial die; and
a periphery of the bottom surface of the micro-sized epitaxial die completely fitting a periphery of a bottom of the growth area.

The conventional micro die forming by the patterned etching procedure, of which the surfaces of the sidewalls are damaged and uneven. The peripheral contours of the top surface and bottom surface of the conventional micro die are not smooth since a large number of etching traces is formed. The present invention provides the growth substrate with the patterned structure disposed thereon to directly form the micro-sized epitaxial die in the growth area of the patterned structure by the natural epitaxial growth. Since the micro-sized epitaxial die is not etched, the periphery of the bottom surface thereof completely fits the periphery of the bottom of growth area.

To achieve the foregoing objective, the manufacturing method of micro light-emitting device has steps of:
(a) preparing a growth substrate having a patterned structure which defines a plurality of micro-sized growth areas separated from each other;
(b) forming a first type epitaxial semiconductor layer on each of the micro-sized growth areas by a natural epitaxial growth;
(c) forming a light-emitting layer only on each of the first type epitaxial semiconductor layer by the natural epitaxial growth;
(d) forming a second type epitaxial semiconductor layer on each of the light-emitting layers by the natural epitaxial growth; and
(e) removing the growth substrate to fabricate a plurality of micro-sized epitaxial dies, each of which has the first type epitaxial semiconductor layer, the light-emitting layer and a second type epitaxial semiconductor layer, and has a top surface, a bottom surface and a plurality of sidewalls connected between the top surface and the bottom surface;
wherein at least one part of a surface of at least one of the plurality of sidewalls of each of the plurality of micro-sized epitaxial dies has a natural epitaxial growth characteristic, including a root mean square roughness of the least one part of the surface of at least one of the plurality of sidewalls is smaller than or equal to 10 nm, or an etch-pit density of the least one part of the surface is smaller than 10⁸/cm², or a flatness tolerance of the least one part of the surface is greater than 0.1 times a thickness of the micro-sized epitaxial die.

Based on the foregoing description, the growth substrate with the plurality of micro-sized growth areas separated to each other is provided to directly form the micro-sized epitaxial dies on the corresponding micro-sized growth areas by the natural epitaxial growth. Since the micro-sized epitaxial die is not etched, the periphery of the bottom surface thereof completely fits the periphery of the bottom of growth area.

Other objectives, advantages and novel features of the invention will become more apparent from the following detailed description when taken in conjunction with the accompanying drawings.

### BRIEF DESCRIPTION OF THE DRAWINGS

FIGS. 1A to 1D are schematic views of steps of process for fabricating a micro light-emitting device in accordance with the first embodiment of the present invention;

FIG. 2 is a side view of a first embodiment of a micro light-emitting device in accordance with the present invention;

FIG. 3A is a top view of FIG. 2;

FIG. 3B is a partial perspective view of FIG. 2;

FIG. 3C is a partial cross-sectional schematic view of FIG. 3A;

FIGS. 4A to 4D are schematic views of steps of process for fabricating a micro light-emitting device in accordance with the second embodiment of the present invention;

FIG. 5 is a side view of the micro light-emitting device of FIG. 4D in one exemplary application;

FIG. 6 is a side view the micro light-emitting device in another exemplary application;

FIG. 7A is a cross-sectional schematic view of a patterned structure for fabricating a micro light-emitting device in accordance with the present invention;

FIG. 7B is a side view of a micro light-emitting device formed with the patterned structure in FIG. 7A;

FIG. 8A is a cross-sectional schematic view of another patterned structure for fabricating a micro light-emitting device in accordance with the present invention;

FIG. 8B is a side view of a micro light-emitting device formed with the patterned structure in FIG. 8A;

FIG. 9A is a cross-sectional schematic view of another patterned structure for fabricating a micro light-emitting device in accordance with the present invention;

FIG. 9B is a side view of a micro light-emitting device formed with the patterned structure in FIG. 9A;

FIG. 10A is a cross-sectional schematic view of another patterned structure for fabricating a micro light-emitting device in accordance with the present invention;

FIG. 10B is a side view of a micro light-emitting device formed with the patterned structure in FIG. 10A;

FIG. 11A is a cross-sectional schematic view of another patterned structure for fabricating a micro light-emitting device in accordance with the present invention;

FIG. 11B is a side view of a micro light-emitting device formed with the patterned structure in FIG. 11A; and

FIG. 12 is a flow chart of a manufacturing method of micro light-emitting device in accordance with the present invention.

### DETAILED DESCRIPTION OF THE EMBODIMENTS

The present invention provides a novel micro light-emitting device. With embodiments and drawings thereof, the features of the present invention are described in detail as follows but are not limited to the embodiments disclosed here.

The micro light-emitting device of the present invention mainly has a light-emitting epitaxial die which is not etched and formed by the natural epitaxial growth. The epitaxial die may be a micro light-emitting diode chip, but not limited to. A natural epitaxial growth process of the epitaxial die is further described as follows.

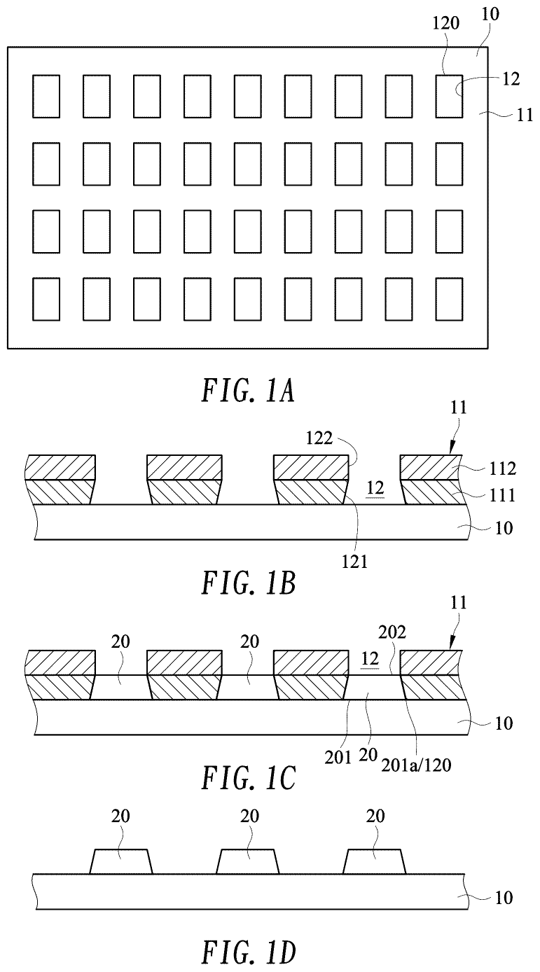

With reference to FIG. 1A, a growth substrate 10 is previously provided. The growth substrate 10 has a patterned structure 11 and the patterned structure 11 defines a plurality of growth areas 12 separated to each other. A size of each growth area 12 matches a size of the epitaxial die as mentioned above. In the present embodiment, the growth areas 12 are arranged in a matrix and have a rectangular periphery at its bottom, but not limited to.

With reference to FIG. 1B, the patterned structure 11 may be consisted of a single material layer, such as a silica layer, or may be consisted of a film layer 111 and a photoresist layer 112 in the present embodiment. The film layer 111 is formed on the growth substrate 10, and a plurality of first cavities 121 corresponding to the growth areas 12 are defined through the film layer 111. The photoresist layer 112 is formed on the film layer 111, and a plurality of second cavities 122 corresponding to the growth areas 12 are defined through the film layer 111. The second cavities 122 respectively communicate with the corresponding first cavities 121 to form the growth areas 12. Furthermore, a shape of the first cavity 121 may differ from or be the same as a shape of the second cavity 122. In the present embodiment, a longitudinal cross-sectional shape of the first cavity 121 is trapezoidal and a longitudinal cross-sectional shape of the second cavity 122 is rectangular.

With reference to FIG. 1C, a micro-sized epitaxial die 20 is formed in the growth area 12 on the growth substrate 10 by the natural epitaxial growth. A periphery 201a of a bottom surface 201 of the micro-sized epitaxial die 20 completely fits a periphery 120 of a bottom of the growth area 12. Since a size of the growth area 12 is micro level, a size of the micro-sized epitaxial die 20 in each growth area 12 is also micro level. Accordingly, the micro-sized epitaxial die 20 is not processed by an etching procedure.

With reference to FIG. 1D, after the patterned structure 11 on the growth substrate 10 is partially removed, a plurality of micro-sized epitaxial dies 20 are obtained.

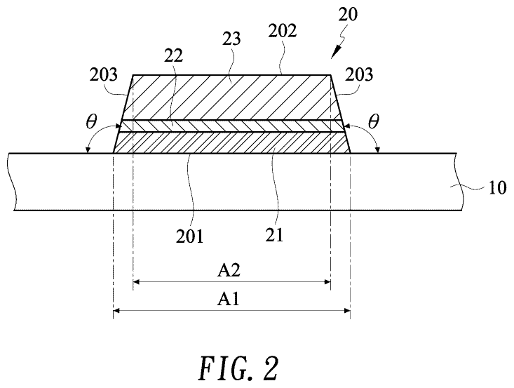

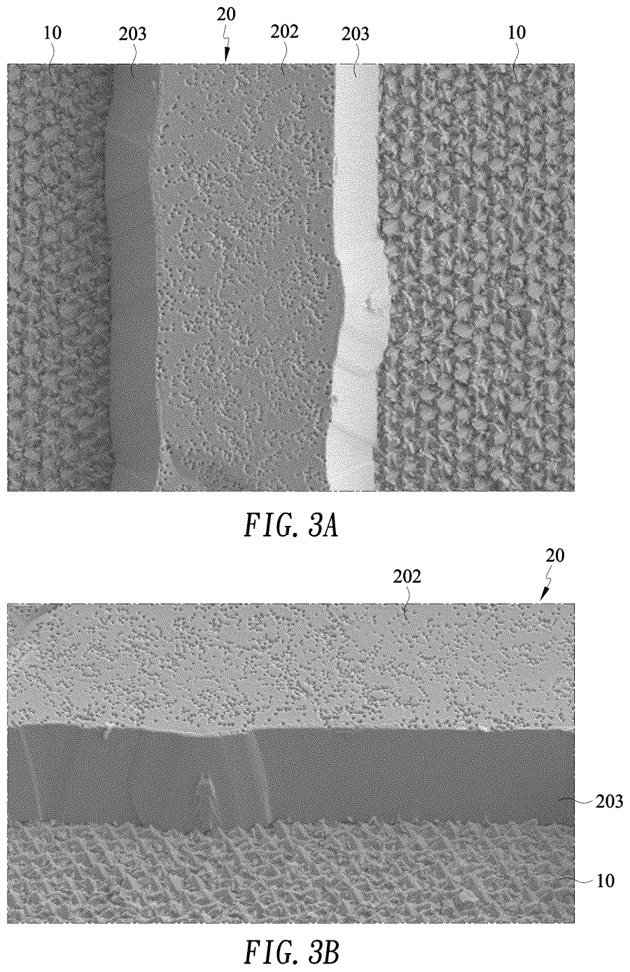

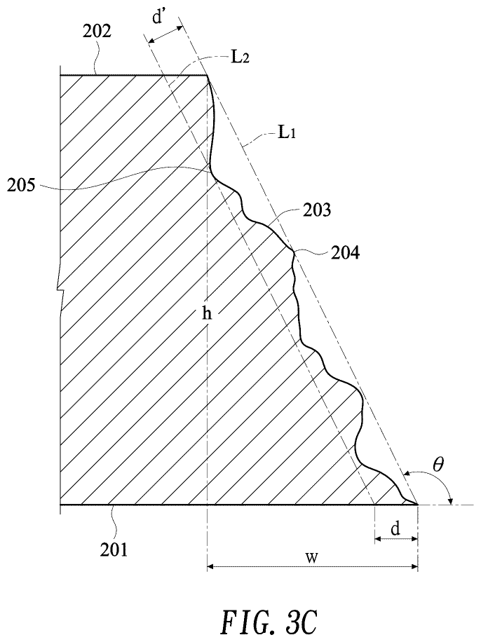

With reference to FIG. 2, a longitudinal cross-sectional view of one of the micro-sized epitaxial dies 20 of FIG. 1D is illustrated. The micro-sized epitaxial die 20 has a top surface 202, a bottom surface 201 and a plurality of sidewalls 203 connected between the top surface 202 and the bottom surface 201. A body of the micro-sized epitaxial die 20 from bottom to top has a first type epitaxial semiconductor layer 21, a light-emitting layer 22 and a second type epitaxial semiconductor layer 23. With further reference to FIGS. 2 and 3A, in the present embodiment, a longitudinal cross-sectional shape of the micro-sized epitaxial dies 20 is trapezoidal so the periphery of the micro-sized epitaxial die 20 has a plurality of sidewalls 203. An angle θ is defined between each sidewall 203 and a bottom surface 201 and the angle θ is between 100 degrees and 130 degrees. An area A1 of the bottom surface 201 of the micro-sized epitaxial dies 20 is greater than a size A2 of the top surface 202. That is, according to the longitudinal cross-sectional shape of the micro-sized epitaxial dies 20, a width of the micro-sized epitaxial dies 20 shrinks from the bottom surface 201 on the growth substrate 10 to the top surface 102, but the shape of the micro-sized epitaxial dies 20 is not limited as described above. Since the micro-sized epitaxial dies 20 is formed by the nature epitaxial growth, a root mean square roughness and an etch-pit density of a surface of each sidewall 203 are smaller than those of the etched surface of the sidewalls. With reference to FIGS. 2 and 3B, FIG. 3B illustrates one sidewall 203 of the micro-sized epitaxial die 20, and irregular dislocations exist on the surface of the sidewall 203. The irregular dislocations are non-periodic and uneven. Since the surface of the sidewall 203 is not etched, the root mean square roughness of the surface of the sidewall 203 is smaller than or equal to 10 nm and the etch-pit density thereof is smaller than 10⁸/cm². The etch-pit density means that a number of the etch-pits per unit area. In a preferred embodiment, the etch-pit density is smaller than 10⁷/cm².

Based on the foregoing description, the micro-sized epitaxial dies 20 is formed by the nature epitaxial growth, so the surface of each sidewall 203 has a plurality of curved surfaces. As shown in FIG. 3C, an enlarged cross-sectional view of the partial sidewall of the micro-sized epitaxial dies 20 is illustrated. The micro-sized epitaxial dies 20 is not etched by isotropic etching or anisotropic etching, a flatness tolerance of the surface of the sidewall 203 is greater than that of the etched surface. In a calculation method of the flatness tolerance, a straight line L1 between an edge of the bottom surface 201 and an edge of the top surface 202 is used as a reference plane. A plurality of convex portions 204 and a plurality of concave portions 205 are further marked and a maximum distance d′ between one of the convex portions 204 and one of the concave portions 205 is defined as the flatness tolerance. The maximum distance d′ is perpendicular to the reference plane and defined between the straight lines L1 and L2 of FIG. 3C. In the general nature epitaxial growth, a distribution zone of the convex portions 204 and concave portions 205 of the micro-sized epitaxial dies 20 is presented by a distance d. The distance d accounts for about 20% of a horizontal width w of the sidewall 203. As shown in FIG. 3C, if a thickness h of the micro-sized epitaxial dies 20 is 5 μm and the angle θ between each sidewall 203 and a bottom surface 201 thereof is between 100 degrees and 130 degrees, the horizontal width w of the sidewall 203 is calculated to be between 0.31 μm and 0.87 μm (the detail of calculation is omitted) and the distance d is also calculated to be between 0.17 μm and 0.64 μm. According to the angle θ is between 100 degrees and 130 degrees, the vertical distances d′ of the convex portions 204 and concave portions 205 are further calculated to be between 0.13 μm and 0.63 μm. If a growth characteristic of epitaxial materials is further considered, the angle θ between each sidewall 203 and a bottom surface 201 is close to 130 degrees. Therefore, a median value of the vertical distances d′ can be calculated to be about 0.5 μm, which is 0.1 times the thickness h. In this instance, the absolute value of the flatness tolerance of the surface of the sidewall 203 is reasonably estimated to be between 0.1 μm and 0.65 μm or is greater than 0.1 times the thickness h of the micro-sized epitaxial dies 20. Since the boundaries of the etched sidewall of the conventional micro die are mostly sharp and straight, the flatness tolerance of the sidewall surface is significantly smaller than the above numerical range.

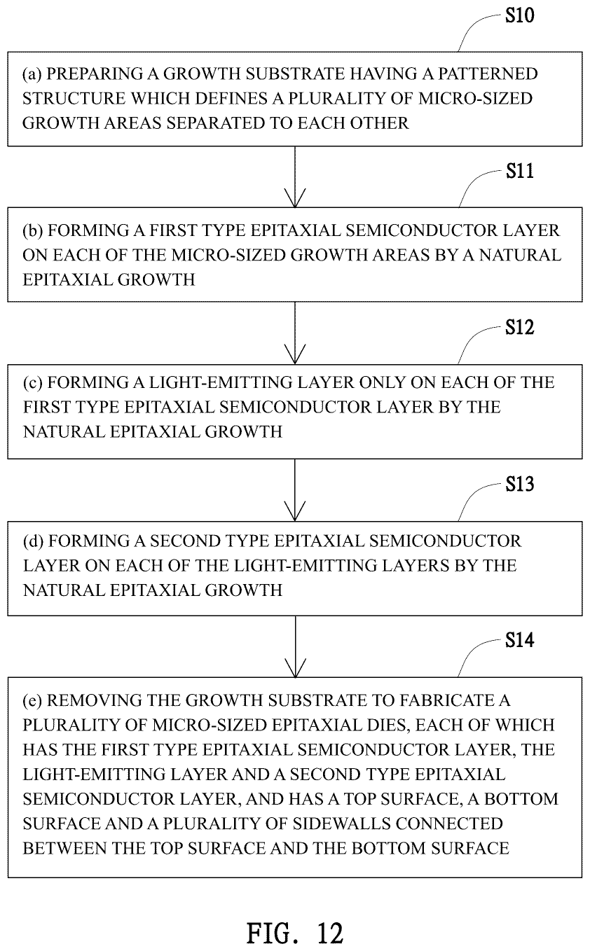

With reference to FIG. 12, a manufacturing method of a plurality of the micro light-emitting devices is illustrated. The manufacturing method has steps of (a) to (e). In the step (a), as shown in FIGS. 1A and 1B, a growth substrate 10 is prepared and has a patterned structure 11, which defines a plurality of micro-sized growth areas 12 separated to each other (S10). In the step (b) a first type epitaxial semiconductor layer 21 on each of the micro-sized growth areas 12 by a natural epitaxial growth, as shown in FIGS. 1C and 2 (S11). In the step (c), a light-emitting layer 22 is only formed on each of the first type epitaxial semiconductor layer 21 by the natural epitaxial growth, as shown in FIGS. 1C and 2 (S12). In the step (d), a second type epitaxial semiconductor layer 23 is formed on each of the light-emitting layers 22 by the natural epitaxial growth, as shown in FIGS. 1C and 2 (S13). In the step (e), as shown in FIGS. 1C and 1D, the growth substrate 10 to fabricate a plurality of micro-sized epitaxial dies 20 is partially removed (S14). As shown in FIG. 2, each micro-sized epitaxial die 20 has the first type epitaxial semiconductor layer 21, the light-emitting layer 22 and a second type epitaxial semiconductor layer 23, and has a top surface 202, a bottom surface 201 and a plurality of sidewalls 203 connected between the top surface 202 and the bottom surface 201. The manufacturing method may further have a step (f). In the step (f), as shown in FIG. 6, a transparent electrode 34 is formed on the top surface 202 of each of the plurality of micro-sized epitaxial dies 20c. An insulation layer 32 is formed on the sidewalls 203 and a part of the bottom surface 201 of each of the plurality of micro-sized epitaxial dies 20c. A first electrode 30 on the insulation layer 32a and the bottom surface 201 of each of the plurality of micro-sized epitaxial dies 20c. A second electrode 31 and a conductive layer 33 are formed on the insulation layer 32b, wherein the second electrode 31 is connected to a transparent electrode 34 on the top surface 202 through the conductive layer 33.

Since the first type epitaxial semiconductor layer 21, the light-emitting layer 22 and a second type epitaxial semiconductor layer 23 are formed by the natural epitaxial growth, at least one part of a surface of at least one of the plurality of sidewalls 203 of each of the plurality of micro-sized epitaxial dies 20 has a natural epitaxial growth characteristic. The natural epitaxial growth characteristic includes a root mean square roughness of the least one part of the surface of at least one of the plurality of sidewalls is smaller than or equal to 10 nm, or an etch-pit density of the least one part of the surface is smaller than 10⁸/cm², or a flatness tolerance of the least one part of the surface is greater than 0.1 times a thickness of the micro-sized epitaxial die.

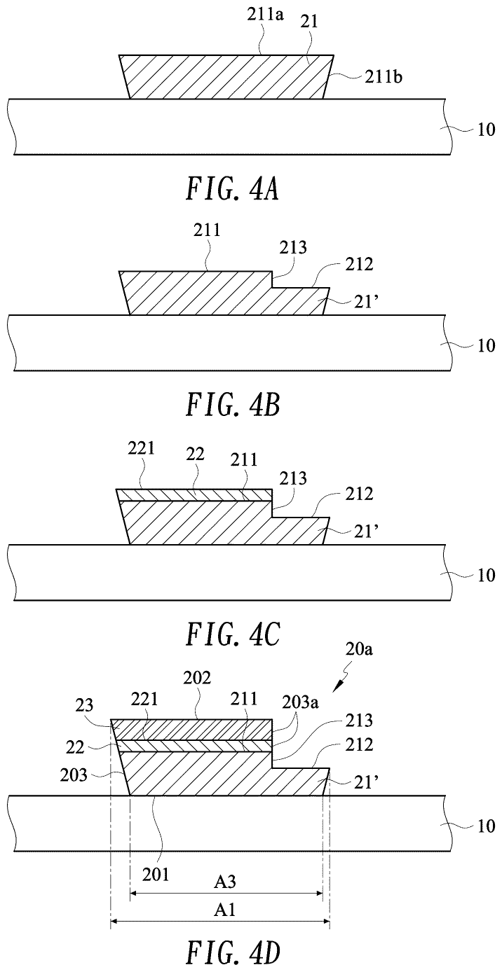

With reference to FIG. 4D, a second embodiment of a micro light-emitting device of the present invention is shown and has a micro-sized epitaxial dies 20a which is similar to the micro-sized epitaxial dies 20 of FIG. 2. A body of the micro-sized epitaxial dies 20a from bottom to top has a first type epitaxial semiconductor layer 21′, a light-emitting layer 22 and a second type epitaxial semiconductor layer 23. A longitudinal cross-sectional shape of the micro-sized epitaxial dies 20a is an inverted trapezoid shape with a wide top and a narrow bottom. The first type epitaxial semiconductor layer 21′ has a first platform 211, a second platform 212 and at least one sidewall part 213. The light-emitting layer 22 is formed on the first platform 211 and the second type epitaxial semiconductor layer 23 is formed on a top surface 221 of the light-emitting layer 22. In the present embodiment, the micro-sized epitaxial die 20a has a projected area A1 on a plane of a bottom surface 201 of the micro-sized epitaxial die 20a, and the projected area A1 is greater than an area A3 of the bottom surface 201.

With reference to FIGS. 4A and 4B, the first type epitaxial semiconductor layer 21 is formed on the growth substrate 10 by the natural epitaxial growth and a top surface 211a and one of sidewalls 211b thereof are etched to form the first type epitaxial semiconductor layer 21′ with a step portion. Therefore, the first type epitaxial semiconductor layer 21′ has the first platform 211, the second platform 212 and the sidewall part 213. The second platform 212 and the sidewall part 213 are formed by etching, not by the natural epitaxial growth. As shown in FIG. 4C, the light-emitting layer 22 is formed on the first platform 211 by the natural epitaxial growth. As shown in FIG. 4D, the second type epitaxial semiconductor layer 23 is formed on the top surface 221 of the light-emitting layer 22 by the natural epitaxial growth. Therefore, only the sidewall part 213 of the first type epitaxial semiconductor layer 21′ is etched and the rest of the sidewalls of the micro-sized epitaxial dies 20a has the natural epitaxial growth characteristics. Specifically, all sidewalls of the light-emitting layer 22 being most correlated with the peak external quantum rate (EQE) are formed by the natural epitaxial growth and the light-emitting layer 22. In the micro light-emitting device, and more particularly to a micro light-emitting diode chip, a sum of the thicknesses of the light-emitting layer 22 and the second type epitaxial semiconductor layer 23 is about 20% of the thickness of the micro-sized epitaxial die 20a. In another fabricating process, even all sidewalls of the micro-sized epitaxial die 20a of FIG. 4D are further etched due to a requirement of isolation, an upper sidewall part 203a above the etched sidewall part 213 still has natural epitaxial growth characteristics. The upper sidewall part 203a consists of a sidewall of the light-emitting layer 22 above the etched sidewall part 213 and a sidewall of the second type epitaxial semiconductor layer 23 above the sidewall of the light-emitting layer 22 above the etched sidewall part 213. An area of the upper sidewall part 203a is about 20% of an area of one sidewall 203 of the micro-sized epitaxial die 20a. Therefore, if the micro-sized epitaxial die 20a is a rectangle with the same side lengths, 5% of the area of all sidewalls 203 of the micro-sized epitaxial die 20a still has natural epitaxial growth characteristics. That is, the 5% area is the area of the upper sidewall part 203a. Therefore, the surface of the partial sidewall with at least 5% area has the natural epitaxial growth characteristics including that the root mean square roughness is smaller than or equal to 10 nm, or the etch-pit density is smaller than 10⁸/cm², or the flatness tolerance of the at least one part of the surface is greater than 0.1 times a thickness of the micro-sized epitaxial die 20a. The above description about ratio and illustrated drawing are only an example for conveniently and easily understanding. In fact, a width of each sidewall 203 of the micro-sized epitaxial die 20a and a position of the second platform 212 may be different according to the selected fabricating process. Therefore, the ratio may vary with a size defined by the growth area 11, such as 3% 7% 10% 14% 18% etc.

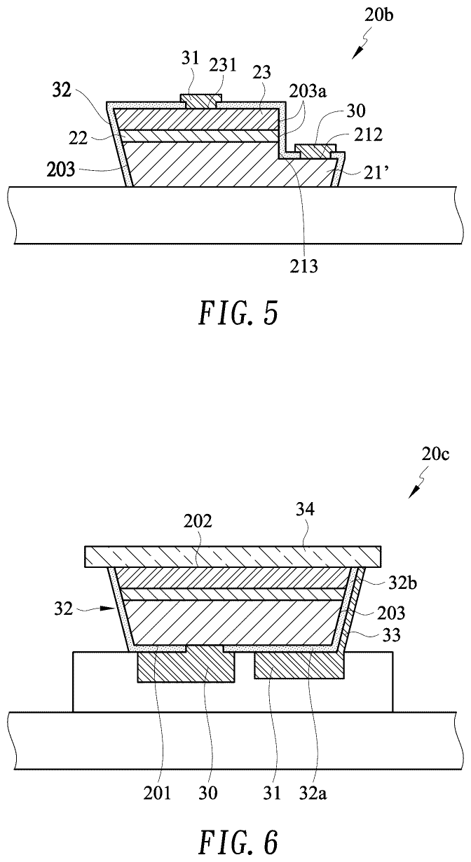

With reference to FIG. 5, one exemplary application of a micro light-emitting device of the present invention is illustrated. A micro-sized epitaxial die 20b of FIG. 5 is similar to the micro-sized epitaxial die 20a of FIG. 4D and further has an insulation layer 32, a first electrode 30 and a second electrode 31. The insulation layer 32 is formed on the sidewalls and a part of the top surface 202 and a part of the etched second platform 212 of the micro-sized epitaxial dies 20b. The first electrode 30 is formed on a second platform 212 of a first type epitaxial semiconductor layer 21′ of the micro-sized epitaxial die 20b. The second electrode 31 is formed on a top surface 231 of a second type epitaxial semiconductor layer 23. In the micro-sized epitaxial die 20b, it is optional that only a surface of a light-emitting layer 22 and a surface of a second type epitaxial semiconductor layer 23 located above an etched sidewall part 213 are formed by the natural epitaxial growth. As shown in FIG. 5, the electrons moving between the first and second electrodes 30, 31 may be close the sidewall part 213. Therefore, since the surface of the upper sidewall part 203a has no dangling bonds thereon, it effectively prevented the electrons from being attracted by the dangling bonds to cause the electronic offset and the bad electrical effects.

A manufacturing method of the micro light-emitting device of FIG. 5 also has the steps (a) to (f). However, in the step (b), as shown in FIGS. 4A and 4B, a top surface 211a and one of sidewalls 211b of each of the first type epitaxial semiconductor layers 21 are etched to form a step portion, wherein each of etched first type epitaxial semiconductor layers 21′ has a first platform 211, an etched second platform 212 and an etched sidewall part 213 connected between the first platform 211 and the etched second platform 212. In the step (c), as shown in FIG. 4C, each of the light-emitting layers 22 is only formed on the corresponding first platforms 211, wherein the light-emitting layer has a plurality of first sides. In the step (d), as shown in FIG. 4D, each of the second type epitaxial semiconductor layers 23 is formed on a top surface 221 of the corresponding light-emitting layer 22, wherein each of the second type epitaxial semiconductor layers 23 has a plurality of second sides. Therefore, in each of the plurality of micro-sized epitaxial dies 20a, one of the plurality of first sides and one of the plurality of second sides are sequentially located above the etched sidewall part 213 constitutes at least one part 203a of the surface of one of the plurality of sidewalls 203 of each of the plurality of micro-sized epitaxial dies 20a. Thus, in each of the plurality of micro-sized epitaxial dies 20a, the etched sidewall part 213 does not have the natural epitaxial growth characteristic. In the step (f), as shown in FIGS. 4D and 5, an insulation layer 32 is formed on the sidewalls 203, a part of the top surface 202 and a part of the etched second platform 212 of each of the plurality of micro-sized epitaxial dies 20a, 20b. A first electrode 30 is formed on the etched second platform 212 of a first type epitaxial semiconductor layer 21′ of the micro-sized epitaxial die 20a, 20b. A second electrode 31 is formed on a top surface 231 of a second type epitaxial semiconductor layer 23.

With reference to FIG. 6, another exemplary application of a micro light-emitting device of the present invention is illustrated. A cross-sectional view of a micro-sized epitaxial die 20c of FIG. 6 is an inverted trapezoid shape with a wide top and a narrow bottom. The micro-sized epitaxial die 20c further has an insulation layer 32 formed on the sidewalls and a part of the bottom surface 201. The first electrode 30 and the second electrode 31 are formed on a part of the insulation layer 32a on the bottom surface 201. The first electrode 30 is connected to the bottom surface 201 and the second electrode 31 is connected to a transparent electrode 34 on the top surface 202 of the micro-sized epitaxial die 20c through a conductive layer 33. The conductive layer 33 may be formed on one part of the insulation layer 32b corresponding to one of the sidewalls 203, thus the micro light-emitting device in FIG. 6 may be formed by the micro-sized epitaxial die 20c with natural epitaxial growth and without etching.

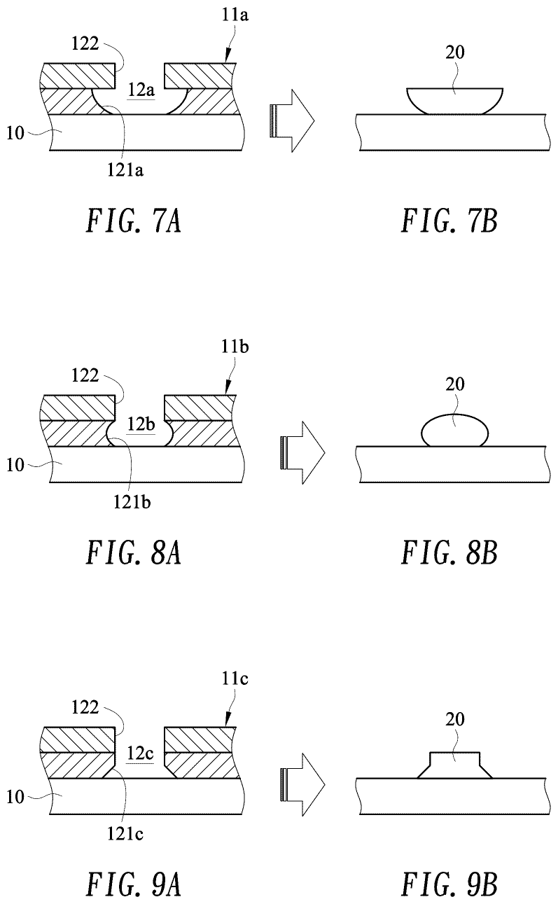

With reference to FIGS. 7A and 7B, another patterned structure 11a on the growth substrate 10 of FIG. 1A is illustrated. A longitudinal cross-sectional shape of a first cavity 121a of a growth area 12a of the patterned structure 11a is a bowl-shape. A longitudinal cross-sectional shape of a second cavity 122 of the growth area 12a of the patterned structure 11a is a rectangular shape. Therefore, a shape of a micro-sized epitaxial die 20 formed in the growth area 12a matches the bowl-shape of the first cavity 121a of the growth area 12a.

With reference to FIGS. 8A and 8B, a longitudinal cross-sectional shape of a first cavity 121b of a growth area 12b of a patterned structure 11b is an ellipse shape. Therefore, a shape of a micro-sized epitaxial die 20 formed in the growth area 12b matches the ellipse-shape of the first cavity 121b of the growth area 12b.

With reference to FIGS. 9A and 9B, a longitudinal cross-sectional shape of a first cavity 121c of a growth area 12c of a patterned structure 11c is a top-rectangular and bottom-trapezoid shape. Therefore, a shape of a micro-sized epitaxial die 20 formed in the growth area 12c matches the top-rectangular and bottom-trapezoid shape of the first cavity 121c of the growth area 12c.

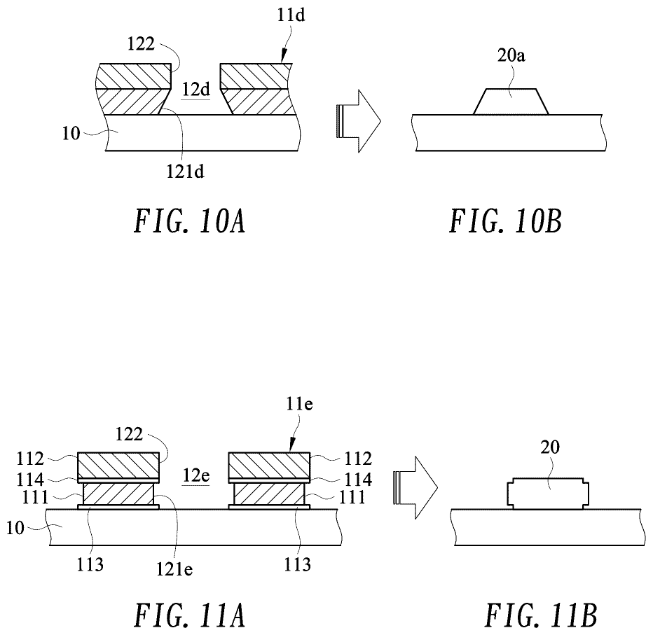

With reference to FIGS. 10A and 10B, a longitudinal cross-sectional shape of a first cavity 121d of a growth area 12d of a patterned structure 11d is an inverted trapezoid shape. With further reference to FIG. 4D, the micro-sized epitaxial die 20a is formed in the growth area 12d and has the inverted trapezoid shape.

With reference to FIGS. 11A and 11B, another patterned structure 11e further has a first material layer 113 and a second material layer 114. The first material layer 113 is formed between the growth substrate 10 and the film layer 111. The second material layer 114 is formed between the film layer 111 and the photoresist layer 112. The first material layer 111 and the second material layer 112 are wider than the film layer 111. Therefore, a longitudinal cross-sectional shape of a first cavity 121e is a cross shape, so as a micro-sized epitaxial die matching the cross shape of the first cavity 121e is formed in the patterned structure 11e. In the present embodiment, an etch rate of the first material layer 113 and an etch rate of the second material layer 114 may be different from that of the film layer 111. Therefore, after etching, the first cavity 121e is formed into cross shape.

Based on the foregoing description, the micro light-emitting device of the present invention mainly has a micro-sized epitaxial die formed by the natural epitaxial growth. A root mean square roughness of at least one part of the surface of at least one of the sidewalls of the micro-sized epitaxial die is smaller than or equal to 10 nm, or an etch-pit density of the at least one part of the surface is smaller than 10⁸/cm², or a flatness tolerance of the at least one partial surface is greater than 0.1 times a thickness of the micro-sized epitaxial die. Since the surfaces of the sidewalls of the micro-sized epitaxial die of the present invention are not damaged by etching to greatly decrease a number of dangling bonds to ease the sidewall damage effect. Also, severe attenuation of the EQE caused by the sidewall damage effect can be prevented while the light-emitting device is miniaturized.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A micro light-emitting device, comprising:
a micro-sized epitaxial die having a top surface, a bottom surface and a plurality of sidewalls connected between the top surface and the bottom surface, and having from bottom to top:
a first type epitaxial semiconductor layer;
a light-emitting layer formed on the first type epitaxial semiconductor layer; and
a second type epitaxial semiconductor layer formed on the light-emitting layer;
wherein at least one part of a surface of at least one of the plurality of sidewalls has a natural epitaxial growth characteristic, including a root mean square roughness of the at least one part of a surface of at least one of the plurality of sidewalls is smaller than or equal to 10 nm, or an etch-pit density of the at least one part of the surface is smaller than 10⁸/cm², or a flatness tolerance of the at least one part of the surface is greater than 0.1 times a thickness of the micro-sized epitaxial die.

2. The micro light-emitting device as claimed in claim 1, wherein
the first type epitaxial semiconductor layer further has:
a first platform;
an etched second platform; and
an etched sidewall part connected between the first platform and the etched second platform, wherein the etched second platform and the etched sidewall part constitutes a step portion;
the light-emitting layer only formed on the first platform of the first type epitaxial semiconductor layer and having a plurality of first sides; and
the second type epitaxial semiconductor layer formed on the light-emitting layer and having a plurality of second sides;
wherein one of the plurality of first sides and one of the plurality of second sides are sequentially located above the etched sidewall part constitutes a part of a surface of one of the plurality of sidewalls of the micro-sized epitaxial die;
wherein in each of the plurality of micro-sized epitaxial dies, one of the plurality of first sides and one of the plurality of second sides are sequentially located above the etched sidewall part constitutes the at least one part of a surface of at least one of the plurality of sidewalls;
wherein the etched sidewall part does not have the natural epitaxial growth characteristic.

3. The micro light-emitting device as claimed in claim 2, wherein the etch-pit density of the at least one part of the surface is smaller than 10⁷/cm², or an absolute value of the flatness tolerance of the at least one part of the surface is between 0.1 μm and 0.65 μm.

4. The micro light-emitting device as claimed in claim 2, wherein an area of the at least one part of the surface is equal to or greater than 5% of an area of the at least one of the plurality of sidewalls.

5. The micro light-emitting device as claimed in claim 1, further comprising:
a transparent electrode formed on the top surface;
an insulation layer formed on the plurality of sidewalls and a part of the bottom surface;
a conductive layer formed on the insulation layer corresponding to one of the plurality of sidewalls;
a first electrode formed on the insulation layer and connected to the bottom surface; and
a second electrode formed on the insulation layer and connected to the conductive layer.

6. The micro light-emitting device as claimed in claim 1, wherein an angle is defined between the at least one of the plurality of sidewalls and the bottom surface, and the angle is between 100 degrees and 130 degrees.

7. The micro light-emitting device as claimed in claim 6, wherein an area of the bottom surface is larger than an area of the top surface.

8. The micro light-emitting device as claimed in claim 1, wherein a longitudinal cross-sectional shape of the micro-sized epitaxial die comprises a bowl-shape, an ellipse-shape, a cross shape, an inverted trapezoid shape, a rectangular shape or a combination thereof.

9. The micro light-emitting device as claimed in claim 1, wherein the plurality of sidewalls have a plurality of curved surfaces.

10. A micro light-emitting device forming on a growth substrate which has a patterned structure defined with a growth area, wherein the micro light-emitting device comprises:
a micro-sized epitaxial die having a top surface, a bottom surface and a plurality of sidewalls connected between the top surface and the bottom surface, and having from bottom to top:
a first type epitaxial semiconductor layer;
a light-emitting layer formed on the first type epitaxial semiconductor layer; and
a second type epitaxial semiconductor layer formed on the light-emitting layer;
wherein at least one part of a surface of at least one of the plurality of sidewalls has a natural epitaxial growth characteristic, including a root mean square roughness of the at least one part of a surface of at least one of the plurality of sidewalls is smaller than or equal to 10 nm, or an etch-pit density of the at least one part of the surface is smaller than 10⁸/cm², or a flatness tolerance of the at least one part of the surface is greater than 0.1 times a thickness of the micro-sized epitaxial die; and
a periphery of the bottom surface of the micro-sized epitaxial die completely fitting a periphery of a bottom of growth area.

11. The micro light-emitting device as claimed in claim 10, wherein
the first type epitaxial semiconductor layer further has:
a first platform;
an etched second platform; and
an etched sidewall part connected between the first platform and the etched second platform, wherein the etched second platform and the etched sidewall part constitutes a step portion;
the light-emitting layer only formed on the first platform of the first type epitaxial semiconductor layer and having a plurality of first sides; and
the second type epitaxial semiconductor layer formed on the light-emitting layer and having a plurality of second sides;
wherein one of the plurality of first sides and one of the plurality of second sides are sequentially located above the etched sidewall part constitutes a part of a surface of one of the plurality of sidewalls of the micro-sized epitaxial die,
wherein in each of the plurality of micro-sized epitaxial dies, one of the plurality of first sides and one of the plurality of second sides are sequentially located above the etched sidewall part constitutes the at least one part of a surface of at least one of the plurality of sidewalls;
wherein the etched sidewall part does not have the natural epitaxial growth characteristic

12. The micro light-emitting device as claimed in claim 11, wherein the etch-pit density of the at least one part of the surface is smaller than 10⁷/cm², or an absolute value of the flatness tolerance of the at least one part of the surface is between 0.1 μm and 0.65 μm.

13. The micro light-emitting device as claimed in claim 11, wherein an area of the at least one part of the surface is equal to or greater than 5% of an area of the at least one of the plurality of sidewalls.

14. The micro light-emitting device as claimed in claim 10, further comprising:
a transparent electrode formed on the top surface;
an insulation layer formed on the plurality of sidewalls and a part of the bottom surface;
a conductive layer formed on the insulation layer corresponding to one of the plurality of sidewalls;
a first electrode formed on the insulation layer and connected to the bottom surface; and
a second electrode formed on the insulation layer and connected to the conductive layer.

15. The micro light-emitting device as claimed in claim 10, wherein an angle is defined between the at least one of the plurality of sidewalls and the bottom surface, and the angle is between 100 degrees and 130 degrees.

16. The micro light-emitting device as claimed in claim 10, wherein a longitudinal cross-sectional shape of the micro-sized epitaxial die comprises a bowl-shape, an ellipse-shape, a cross shape, an inverted trapezoid shape, a rectangular shape or a combination thereof.

17. The micro light-emitting device as claimed in claim 10, wherein the surfaces of the plurality of sidewalls have a plurality of curved surfaces.

18. A manufacturing method of micro light-emitting device, comprising steps of:
(a) preparing a growth substrate having a patterned structure which defines a plurality of micro-sized growth areas separated from each other;
(b) forming a first type epitaxial semiconductor layer on each of the micro-sized growth areas by a natural epitaxial growth;
(c) forming a light-emitting layer only on each of the first type epitaxial semiconductor layer by the natural epitaxial growth;
(d) forming a second type epitaxial semiconductor layer on each of the light-emitting layers by the natural epitaxial growth; and
(e) removing the growth substrate to fabricate a plurality of micro-sized epitaxial dies, each of which has the first type epitaxial semiconductor layer, the light-emitting layer and a second type epitaxial semiconductor layer, and has a top surface, a bottom surface and a plurality of sidewalls connected between the top surface and the bottom surface;
wherein at least one part of a surface of at least one of the plurality of sidewalls of each of the plurality of micro-sized epitaxial dies has a natural epitaxial growth characteristic, including a root mean square roughness of the least one part of the surface of at least one of the plurality of sidewalls is smaller than or equal to 10 nm, or an etch-pit density of the least one part of the surface is smaller than 10⁸/cm², or a flatness tolerance of the least one part of the surface is greater than 0.1 times a thickness of the micro-sized epitaxial die.

19. The manufacturing method as claimed in claim 18, wherein
in the step (b), a top surface and one of sidewalls of each of the first type epitaxial semiconductor layers are etched to form a step portion, wherein each of the etched first type epitaxial semiconductor layers has a first platform, an etched second platform and an etched sidewall part connected between the first platform and the etched second platform;
in the step (c), each of the light-emitting layers is only formed on the corresponding first platforms, wherein the light-emitting layer has a plurality of first sides; and
in the step (d), each of the second type epitaxial semiconductor layers is formed on a top surface of the corresponding light-emitting layer, wherein each of the second type epitaxial semiconductor layers has a plurality of second sides;
wherein in each of the plurality of micro-sized epitaxial dies, one of the plurality of first sides and one of the plurality of second sides are sequentially located above the etched sidewall part constitutes at least one part of the surface of one of the plurality of sidewalls of each of the plurality of micro-sized epitaxial dies;
wherein in each of the plurality of micro-sized epitaxial dies, the etched sidewall part does not have the natural epitaxial growth characteristic.

20. The manufacturing method as claimed in claim 18, further comprising a step (f) having acts of:
forming a transparent electrode on the top surface of each of the plurality of micro-sized epitaxial dies;
forming an insulation layer formed on the sidewalls and a part of the bottom surface of each of the plurality of micro-sized epitaxial dies;
forming a first electrode on the insulation layer and the bottom surface of each of the plurality of micro-sized epitaxial dies; and
forming a second electrode and a conductive layer on the insulation layer, wherein the second electrode is connected to a transparent electrode on the top surface through the conductive layer.

21. The manufacturing method as claimed in claim 19, further comprising a step (f) having acts of:
forming an insulation layer on the sidewalls, a part of the top surface and a part of the etched second platform of each of the plurality of micro-sized epitaxial dies;
forming a first electrode on the etched second platform of a first type epitaxial semiconductor layer of the micro-sized epitaxial die; and
forming a second electrode on a top surface of a second type epitaxial semiconductor layer.
